(19) United States
(12) Patent Application Publication
(10) Pub. No.: US 2002/0068373 A1
(43) Pub. Date: Jun. 6, 2002

(54) Method for fabricating light emitting diodes

(75) Inventors: Yu-Hwa Lo, San Diego, CA (US); Zuhua Zhu, San Jose, CA (US); Tuoh-Bin Ng, Santa Clara, CA (US)

Correspondence Address: KEVIN P B JOHNSON, FISH & NEAVE, CUSTOMER NO 1473, 1251 AVENUE OF THE AMERICAS, NEW YORK, NY, 10020, US

(73) Assignee: Nova Crystals, Inc.

(21) Appl. No.: 09/728,636

(22) Filed: Dec. 1, 2000

Related U.S. Application Data
(60) Provisional application No. 60/182,738, filed on Feb. 16, 2000.

(51) Int. Cl. H01L 21/00

(52) U.S. Cl. 438/33; 438/26

(57) ABSTRACT

This invention describes a method for fabricating light-emitting diodes with an improved external quantum efficiency on a transparent substrate. The LED device structure is mounted face-down on and bonded to a handling wafer. The LED dies on the transparent substrate are separated by applying mutually aligned separation cuts from both sides of the transparent substrate and by then cutting through the handling wafer and the substrate wafer. This method allow the use of substrates that are difficult to thin and cleave. Contacts can be applied from one side of the devices only. The method is suitable for low cost high volume manufacturing.

### CROSS-REFERENCE TO OTHER PATENT APPLICATIONS

This application claims the benefit of U.S. provisional Patent Application No. 60/182,738, filed Feb. 2, 2000.

### FIELD OF THE INVENTION

The invention is directed to a method for fabricating semiconductor devices on substrates that are difficult to cleave, and more particularly to a method for producing light-emitting diodes (LEDs) with a higher light output efficiency and at lower cost.

### BACKGROUND OF THE INVENTION

Light emitting diodes (LEDs) belong to a class of solid state light emitting devices which directly convert electricity into light. Unlike conventional electric light sources such as incandescent lamps which produce light by electrically heating a filament, LEDs produce light through injection electroluminescence and/or electron-hole recombination. Semiconducting material systems which have so far been successfully used to fabricate practical LEDs include (Al,Ga)As, (Al,In,Ga)P, (Al,In,Ga)N, SiC, as well as several classes of polymer. The light emitting polymers are also sometimes referred to as organic semiconductors, and the polymer LED as organic LED (OLED).

LEDs enjoy advantages over most other forms of light sources in their energy conversion efficiency, low operating voltages, compactness, long lifetimes and fast switching responses. The earliest LEDs were fabricated from GaAs and emit in the infrared spectral region which is invisible to the human eye. With the advent of high brightness InGaAlP LEDs in recent years, practical visible red, orange and yellow light sources with brightness rivaling and surpassing light bulbs have been realized. This is closely followed beginning in 1993 by the introduction of bright green, blue, violet and even ultraviolet (UV) LEDs fabricated from a GaN-based material system. Together, these diode make possible a full color display with sufficient brightness that can be viewed outdoors, with white light LEDs having the potential to replace incandescent light bulbs as a main light source for general illumination.

In LED, light is emitted from the junction between a p-type and an n-type semiconducting region. The simplest LED can be fabricated with just a p-n junction. Most high efficiency devices use heterostructures and an active layer sandwiched between the p- and n-type regions to improve the light emitting efficiency, also referred to as quantum efficiency, and to obtain the desired emission wavelengths. Two different values of the quantum efficiency are normally quoted for LED, the internal quantum efficiency (IQE) and the external quantum efficiency (EQE).

The internal quantum efficiency (IQE) refers to the basic conversion efficiency of electron-hole pairs into photon. An electron-hole pair may recombine through a number of mechanisms, either radiatively or non-radiatively. The internal quantum efficiency is a measure of the radiative fraction of the recombination process. Factors which influence internal quantum efficiency include fundamental material characteristics, material quality and device design. The most important material characteristics that determine whether a semiconductor can be efficient light emitter is the band structure. More specifically, an efficient electroluminescent material must have a direct bandgap, i.e. its electron and hole must be able to recombine radiatively without involving a phonon. Efficient optoelectronic materials, such as GaAs, InP and GaN, have a direct bandgap. However, the presence of impurities and structural defects in a material can adversely affect the radiative recombination. The effect of defects on the electroluminescent efficiency is material-dependent, with GaN having an exceptional high tolerance for dislocations before the luminescent efficiency is seriously impaired. Lastly, the recombination efficiency of LEDs can also be improved by proper design of the device structure, for example, through carrier confinement layers (heterostructures) or by employing quantum effects in quantum wells and quantum dots structures.

The external quantum efficiency (EQE) measures the amount of light that is emitted from the LED as a function of the electrical input current. While some highly efficient device structures can have an internal quantum efficiency (IQE) of close to 100%, the EQE rarely exceeds 10%. Several device designs are known in the art that enhance the EQE: for example, the LEDs can be encapsulated in epoxy with a refractive index intermediate between the LED material and air, and/or heterostructures can be employed. The former method reduces internal reflection by reducing the refractive index discontinuity at the boundaries of the LED; whereas the latter reduces re-absorption of emitted photon by the surrounding active layers which have a higher bandgap and are therefore transparent to the emission.

Among factors limiting EQE are the internal reflection of light at the boundary of the LED, re-absorption of photons by the LED material, and light blocking by non-transparent features on the device, such as the substrate and/or metal contact pads. In particular, for thick substrates, light emitted in the direction of the substrate may be completely absorbed. This factor alone can account for as much as a 50% reduction in the EQE. Conventional approaches to improve external QE have hence mostly concentrated on alleviating the two effects of absorption and internal reflection.

Before the introduction of GaN based blue and green LED, high brightness visible LEDs were fabricated exclusively from epitaxially grown AlInGaP on GaAs substrates. These LEDs emit in red, orange and yellow spectral range. For these LEDs, absorption by the substrate has been the major factor in the loss of EQE.

In one prior art approach, the decrease in the EQE due to substrate absorption has been alleviated through the use of Bragg reflector epitaxially grown between the LED structure and the substrate. A Bragg reflector consists of a stack of alternating thin layers with different refractive indices which, through the optical interference effect, can be designed to be highly reflective for light of a particular wavelength. For LEDs grown on GaAs substrate, this is can be achieved by growing alternating layers of GaAs and GaAlAs which are closely lattice matched, and have a suitable refractive index difference. Disadvantageously, the Bragg reflector is wavelength selective, reflecting predominantly light incident at angles close to the normal of the reflector plane. High brightness InGaAlP LEDs with Bragg reflectors can emit up to 10 lumens per watt.

In another prior art approach disclosed in U.S. Pat. No. 5,376,580, high brightness InGaAlP visible LEDs are produced using transparent substrates. Here the absorbing GaAs substrate of an InGaAlP LED wafer that does not have the Bragg reflector, is removed by lapping and etching, and the remaining epitaxial layers are bonded to a GaP substrate by, for example, wafer fusion. GaP has an indirect bandgap of 2.26 eV and is transparent to the red/orange/yellow light emitted by the InGaAlP LED structure. Such LEDs have a recorded efficiency of more than 25 lumens/watt.

Starting around 1993, blue and green GaN LEDs based on InGaN/AlGaN and grown on either sapphire or SiC substrates became commercially available . Both of these substrate materials are transparent to the LED emission. Sapphire substrates have the advantages of low costs and high quality, but has the disadvantage of being an electric insulator. SiC substrates , on the other hand, are electrically conducting, but expensive.

With sapphire being insulating, both p- and n-type contacts of GaN LEDs must be placed on the top surface, which complicates the manufacturing processes and increases costs. Moreover, the overall area available for light emission is also reduced by the surface area of the contact. Due to the low hole mobility (μₚ<20 cm²/V·s) as compared to the electron mobility (μₙ>600 cm²/V·s), the light-emitting area is constrained by the availability of holes in the active layer, essentially follows the surface coverage of the p-contact. Although the p-contact can be made semi-transparent, a substantial portion of the LED emission may still be absorbed by the p-contact disposed on the top surface, which is normally where most of the light will be collected. This effectively offsets much of the advantage provided by transparent substrates. Currently practiced GaN epitaxial growth technology essentially prevents growth of GaN LEDs with the n-type side up.

In an alternative approach, the LED chip can be mounted with the top surface (p-type) downward, so that most of the emission emerges from the substrate side. This is tenable in the cases where the substrate is conducting. However, the non-conducting sapphire substrate representing the preferred substrate for GaN LEDs then requires that both p- and n-contacts face downward. In this case, flip-chip bonding to, for example, a patterned substrate could be employed. However, flip-chip packaging tends to have a low throughput, and is hence not suitable for the low costs high volume manufacturing environment typically found in the LED industry.

It would therefore be desirable to provide a cost-effective method to fabricate an LED, in particular a GaN-based LED and a high-efficiency InGaAlP LED, with an improved light extraction efficiency on a transparent substrate.

### SUMMARY OF THE INVENTION

In this invention, a method is proposed for producing semiconductor devices, such as an efficient LED, on a transparent substrate, in particular a substrate that is difficult to etch or cleave. The transparent substrate can be conducting or insulating.

Advantageously, the light passes through the transparent substrate unobstructed by opaque or semi-transparent electrical contact pads. The inherent thickness of the substrate, relative to the layers in the LED structure, also reduces internal reflection and enhances the coupling of light out.

Since obstruction of light is no longer an issue, the contact pads can be made as large as necessary and thereby enhances current spreading and reduces contact resistance.

The backside of the transparent substrate, where most of the emission emerges, can be lapped into the desired roughness to improve its emissivity.

Since the light emitting active layer is close to the LED top surface, selecting the handling wafer to be of a good thermal conducting material can improve heat sinking and thus reduce the heating of the light emitting junction which usually causes deterioration of the internal quantum efficiency.

According to one aspect of the invention, a method is disclosed for producing a device die by forming a device structure on a first substrate and applying first separation marks on the device structure. The first separation marks extending partially through the first substrate. A second substrate is then placed against a top surface of the device structure opposite the first substrate and facing the first separation marks, whereafter second separation marks are applied on the first substrate on a side of the substrate facing away from the first separation marks. The second separation marks are aligned with the first separation marks. The so formed composite structure is then cut through the first substrate and the second substrate to produce the device die.

According to another aspect of the invention, LEDs devices are produced from a substrate wafer with an LED device structure by defining LED dies on the LED device structure and applying contacts to the LED devices that face away from the substrate wafer for supplying an electric voltage to the LED dies. A first separation mark is then placed between the LED dies on the side of the substrate wafer with the LED device structure. A handling wafer with formed electrodes that can mate with the contacts of the LED structure is then placed against the LED device and bonded so that the electrodes mate with the contacts of the LED structure. A second separation mark substantially aligned with the first separation mark is then placed on a side of the substrate wafer facing away from the LED device structure. A separation cut extending through the substrate wafer and the handling wafer and laterally offset from the first and second separation mark is then applied to separate the LED dies to form the LED devices.

Embodiments of the invention may include one or more of the following features. The first substrate can be transparent and made of, for example, sapphire. The device structure can include LEDs and detectors, but may also be applied to other semiconductor devices, such as high-power transistors. Preferably, least two contacts are arranged on a top surface of the device. The first substrate can be bonded to the second substrate, for example, by wafer-bonding or fusion, and the second substrate may include contact pads associated with the at least two contacts. The second substrate can be made of a metal, a semiconductor or a polymer and may include an optically reflective layer implemented, for example, as a metal layer or a dielectric stack. The reflective layer can have an insulating layer on either or both sides. The LED device structure can be made of Si (for example, GaAs-on-Si), (AlGaIn)As, (AlGaIn)P and/or (AlGaIn)N, whereas the second substrate can be Si, GaAs and/or SiC. The cuts through the first and the second substrate can be applied at a location that is offset from the first and second separation marks, to facilitate access to the contact pads and expose at least one of the contact pads on the second substrate. Electric power can be supplied to the LED device through the electrically conducting handling wafer.

Further features and advantages of the present invention will be apparent from the following description of preferred embodiments and from the claims.

### BRIEF DESCRIPTION OF THE DRAWINGS

The following figures depict certain illustrative embodiments of the invention in which like reference numerals refer to like elements. These depicted embodiments are to be understood as illustrative of the invention and not as limiting in any way.

FIG. 1a shows LED device layers grown on an insulating substrate and scribe marks between LED dies;

FIG. 1b shows the LED device wafer of FIG. 1a bonded to a handling wafer;

FIG. 1c shows the bonded LED device wafer of FIG. 1b with opposing scribe marks;

FIG. 1d shows the bonded LED device wafer of FIG. 1c with cuts for die separation;

FIG. 1e shows the separated dies of FIG. 1d with exposed contacts;

FIG. 2a shows a transparent substrate with LEDs and a handling wafer with matching contacts before bonding;

FIG. 2b shows the substrate and the handling wafer of FIG. 2a after bonding;

FIG. 2c shows the LEDs of FIG. 2a after separation;

FIG. 3 shows the improvement in LED output power of the GaN LED of FIG. 2c over a conventional LED having a top p-contact;

FIG. 4a-e show a process flow for bonding AlInGaP LEDs to a handling wafer, wherein the substrate of the LEDs is removed.

### DETAILED DESCRIPTION OF CERTAIN ILLUSTRATED EMBODIMENTS

The invention is directed to the fabrication of an LED, in particular a GaN-based LED and a high-efficiency InGaAlP LED, with an improved light extraction efficiency on a transparent substrate. In particular, with the method described herein, an entire wafer can be processed at once into separate dies, wherein contacts can be easily placed on a top surface of the dies.

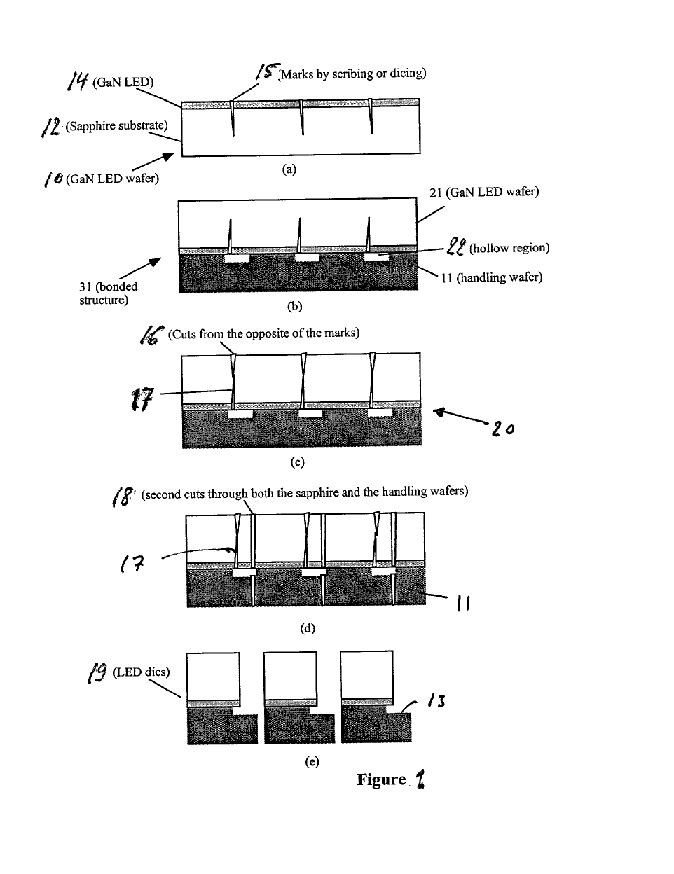

FIGS. 1a-e depict schematically the concept underlying the present invention. As seen in FIG. 1a, an LED wafer 10 includes an LED structure 14 grown on a transparent substrate 12, for example sapphire, using growth methods known in the art. In the depicted example, an electrically insulating substrate is employed so contacts (not shown) to both the p- and n-type layers, respectively, are made on the top surface. Selective area etching may be necessary in order to expose the buried layers of conductivity type opposite to the top layer. For example, if the top layers are p-type, then part of the top layers must be etched off to expose the n-type layers underneath, and vice versa.

As seen in FIG. 1b, first separation marks 15 are placed on the front side of the sapphire substrate, i.e., the side of the sapphire substrate with the LED structure, using for example, a conventional scribing, sawing or dicing technique. The separation mark 15 can weaken the structure 10 without breaking the sapphire substrate 12. The marked LED wafer 10 is then bonded to a handling wafer 11 that for subsequently exposing a contact area may be patterned to include recessed regions 22 so that the marked lines are not in contact with the handling wafer.

The handling wafer can consist of a conducting substrate having disposed on a top surface electrodes (not shown) that match the p- and n-type LED contacts on the LED wafer 10. The handling wafer may be conductive metal, semiconductor or polymer. At least one of the electrodes, matching either the p- or n-contact of the LED, is insulated from the conductive handling wafer by an interposed insulating material to prevent circuit shortage. The backside of the handling wafer is metalized to form the other of the electrodes and create a conductive contact. A conventional heating or annealing step may be required to realize a good ohmic contact.

The matching electrodes and contact pads of the LED wafer and the handling wafer are then aligned and the two wafers are pressed together and wafer-bonded. Wafer bonding may require heating the wafer pair to a suitable elevated temperature, for example, above the melting temperature of a solder used for bonding the wafers.

After bonding, either one or both of the LED and handling wafers may be thinned to an appropriate thickness to facilitate subsequent device dicing.

As seen in FIG. 1c, another mark 16 that is aligned with and located on the opposite side of the first mark 15 is applied to the bonded sapphire substrate. Because the structure has been weakened by the marks 15, 16, the sapphire substrate 12 will crack through its entire thickness at the marked position 17 whereas leaving the handling wafer underneath intact. As seen in FIG. 1d, cuts 18 that are offset with respect to the marked positions 17 are made through the LED wafer 10 with the LED structure 14 and the handling wafer 11 to separate the LED dies 19 (FIG. 1e). When the LED device dies are packaged, one electrical connection is made on the backside of the handling wafer, while another is made from the top onto the exposed electrode insulated from the handling wafer. This process requires only conventional packaging technology, and is feasible for low cost high volume manufacturing.

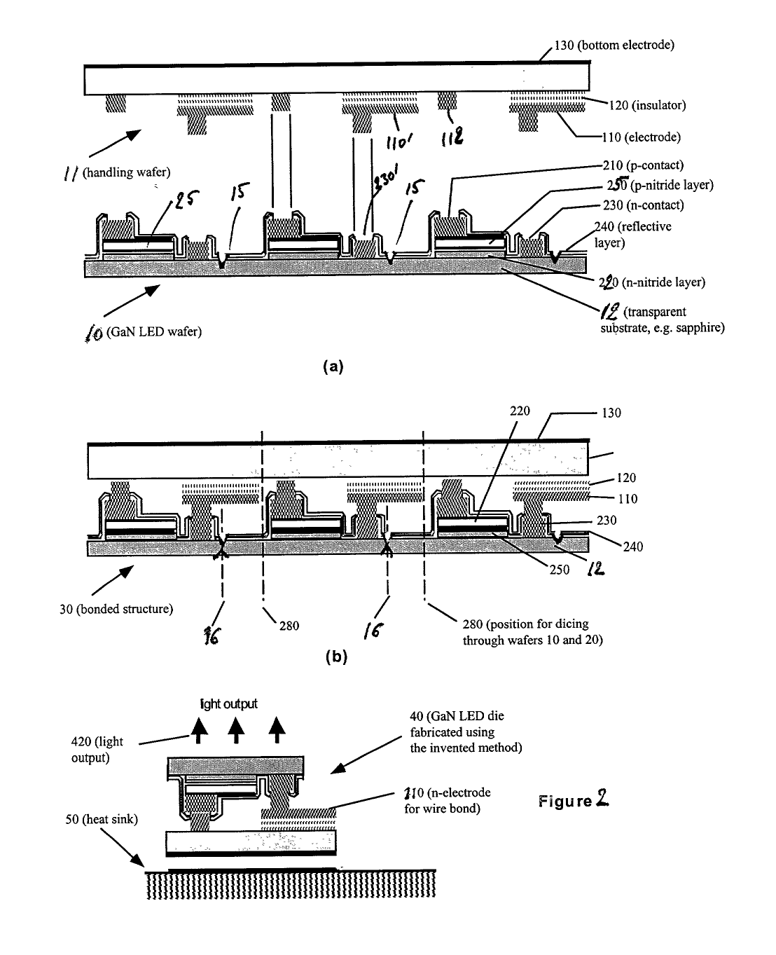

Referring now also to FIGS. 2a-c, the method outlined above is now depicted in greater detail with reference to GaN-based LEDs grown on sapphire substrate. The sapphire substrate is transparent to all electroluminescent emission wavelengths from (In,Al,Ga)N that have been demonstrated. In addition, since sapphire is insulating, both p- and n-type electrical contacts have to be made on top of the LED structure. A suitable choice of the material used for the handling wafer also improves heat sinking of the LEDs, since sapphire has a relatively poor thermal conductivity, thereby further enhancing the efficiency and reliability of the GaN-on-sapphire LEDs.

A GaN-on-sapphire LED structure is shown in FIG. 2a. Conventional epitaxy is used to produce an GaN LED wafer 10 which includes a sequence of (InGaAl)N layers 220, 250 disposed on a sapphire substrate 12. To achieve high quality LED material with current growth techniques, an n-type layer 220 is grown first, followed by an active layer(not shown) and a p-type layer 250. Because the sapphire substrate 12 is an insulator, mesas 25 have to be etched through the p-type layer 250 and active layer(s) to expose the n-type layer 220 for making n-type contacts 230. Due to the height of the mesa 25, the p-type contact 210 disposed on the p-type layer 250 and the n-type contact 230 are at a different height. The p-contact tends to be more resistive and hence should be made as large as possible to reduce the contact resistance and maximize the light emitting area. Instead of making the p-contact semi-transparent, which places severe restrictions on its thickness and thus undermines its reliability, the p-contact in the present embodiment is made reflective. To capture the light emerging from the mesa sidewalls, a reflective coating can be deposited to cover the whole top surface except for the contact pads. The reflective coating can be a metal layer, provided the metal layer is sandwiched between two insulating layers, such as SiO₂, to prevent short-circuiting of the p- and n-contacts .

An exemplary handling wafer with electrodes 110, 112 matching the LED contacts 210, 230 described above is also shown in FIG. 2a. The handling wafer 11 is preferably electrically conducting so that the electrode 112 is connected to a bottom electrode 130. Si which is inexpensive and has a good thermal conductivity, can be used as a handling wafer. However, Si has a significant thermal expansion coefficient mismatch with GaN and sapphire, which may complicate wafer bonding. GaAs has a good thermal expansion coefficient match with GaN, but suffers from a relatively poor thermal conductivity. Polycrystalline α-SiC is inexpensive and has excellent thermal conductivity, but its hardness may add complexity to the LED device separation.

In GaAs-based and GaP-based semiconductor devices are typically separated by sawing and/or cleaving. Because of the hardness of the sapphire material, which has a typical thickness of about 100 micrometers after lapping, it is difficult to cut through the sapphire substrate without breaking or damaging the handling wafer placed on the device side of the sapphire wafer. For this reason, as discussed above with reference to FIG. 1a, a first separation cut 15 is made in the sapphire substrate 12 on the device side of the GaN nitride wafer between the p-type contact 210 of a first LED die and the n-type contact 230′ of an adjacent LED die before the handling wafer 11 is pressed against the device wafer 12.

The two metal electrodes 110, 112 on the handling wafer 11 are designed to match the respective p- and n-contact pads 210, 230 of the LED. The n-electrode 110 is deposited on a pedestal 120 of insulating material, such as SiO₂. The height of the electrodes is selected so as to compensate for the mesa height of the LED. Brought into close proximity and aligned, the LED wafer 10 and the handling wafer 11 can then be pressed together and fused at an elevated temperature, as shown in FIG. 2b. Thereafter, the LED substrate and/or the handling wafer can be lapped to reduce their thickness, for example, to below 150 μm. The backside of the handling wafer is then metalized to provide electrical contact to the p-contact 210. A second separation cut 16 aligned with first separation cut 15 is then made in the sapphire substrate 12 on the opposite side of the first separation cut 15. The two separation cuts 15, 16 will cause the LED substrate 12 to crack along the line 270, as indicated in FIG. 2b, while the undamaged handling wafer 11 keeps the LED dies 25 together.

As also indicated in FIG. 2b, a separation cut 280 is made through the entire wafer structure, which includes the GaN LED wafer and the LED-handling wafer, between the p-electrode 110 of a die 25 and the n-electrode 110′ of an adjacent die 25. The portion of the LED wafer 10 located between the separation cut 280 and the crack line 270 will then become completely detached from the wafer 10 and fall out. This exposes the n-electrode 110 from the top for wire bonding. The completed LED die 40 can then be mounted in a conventional manner on a base 50 which acts as the positive terminal and heat sink, as shown in FIG. 2c. Light 420 is emitted through the transparent substrate 12.

The process described above is a wafer-scale process that will lead to cost advantages over the conventional flip-chip bonding process. In an alternative embodiment (not shown), the mark on the device side of the sapphire substrate 12 may be aligned to the cleavage plane of a (0001) sapphire substrate (the most popular crystal orientation for GaN growth) and cut deep enough so that the sapphire wafer may cleave along the crystal plane by applying sufficient pressure from the opposite (uncut) side of the substrate 12 after bonding and lapping. Alternatively, a deep enough mark may be applied on the device side of the sapphire substrate 12 so that the sapphire wafer will break along the mark during lapping.

It should be mentioned that several methods can be employed to bond the LED sapphire substrate to the handling wafer while aligning the corresponding p- and n-electrodes. A thick layer of metal or metal compound (e.g. Au/Ge, Sn/Pb) may be electroplated on the handling wafer so that a strong bond can be established between the electrodes of two wafers through the formation of a metal alloy. Several methods are available to align the LED wafer to the handling wafer. They may be mechanically aligned using instrument similar to a contact mask aligner. The fact that sapphire substrate is transparent makes the task easy. Self-alignment may also be achieved using the surface tension of the bonding metal in the same fashion as flip-chip bonding.

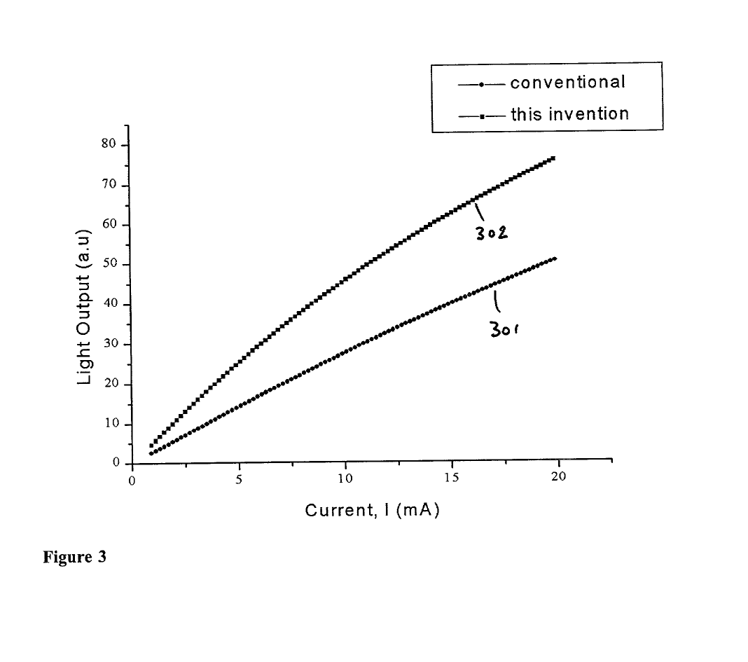

FIG. 3 shows the light output vs. current input curves for two GaN blue LED dies. A first curve 301 is the light output vs. current input for a GaN LED mounted in a conventional manner (LED structure up; sapphire substrate down; and current applied through a transparent top p-contact), while the second curve 302 is the light output vs. current input for a GaN LED produced using the method of the invention. The latter shows an improvement of approximately 60% in the optical output power at a current input of 20 mA.

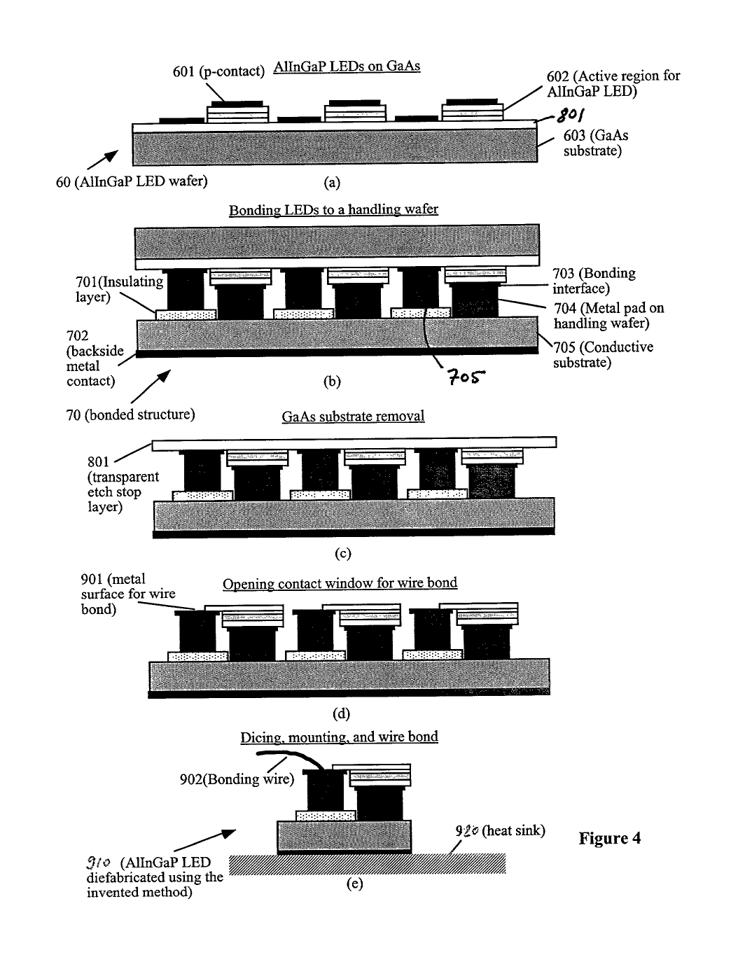

The invented method can also be applied to AlInGaP red, orange, and yellow LEDs, although these LEDs are normally grown on a lattice-matched opaque GaAs substrate. FIGS. 4a-e summarize an exemplary process for AlInGaP LEDs. As seen in FIG. 4a, the p-contact 601 and the n-contact 604 of the AlInGaP LED are located on the same side of the LED wafer 60 as the active region 602. Current spreading is less of a problem in AlInGaP LEDs, so that the p-contact 601 can be made small and thin, allowing light to be transmitted therethrough. As discussed above with reference to FIGS. 2a-c and seen in FIG. 2b, the wafer 60 is bonded to a handling wafer 705 having matching electrodes 704, 705 after both p- and n- contacts 601, 604 are formed on the AlInGaP LED wafer. After wafer bonding, the GaAs substrate 603, on which the AlInGaP LEDs are grown, is removed to an etch stop layer 801 using, for example, lapping and/or chemical etching, as illustrated in FIG. 4c. The etch stop layer 801 is preferably transparent to the emitted light. The etch stop layer 801 (e.g., GaAlAs) is selectively removed using lithography and etching to expose a contact region 901 for wire bonding (e.g., n-contact), as depicted in FIG. 4d. As seen in FIG. 4e, the finished device 910 can be mounted in a conventional manner to a heat sink 920 providing the p-contact, and a bonding wire 902 can be attached to the contact region 901. The process described with reference to FIG. 2 does not rely on separation marks and separation cuts for separating the LED dies, since AlInGaP and GaAs-based compound semiconductors can be readily wet and dry etched.

While the invention has been disclosed in connection with the preferred embodiments shown and described in detail, various modifications and improvements thereon will become readily apparent to those skilled in the art. For example, the method described above can not only be applied to light-emitting devices, but also to other semiconductor devices, such as detectors, in which case Si and Ge as well as other suitable III-V or II-VI materials known in the art can be used. Accordingly, the spirit and scope of the present invention is to be limited only by the following claims.

What is claimed is:

1. A method of producing a device die comprising:
disposing a device structure on a first substrate;
applying first separation marks on the device structure, the first separation marks extending partially through the first substrate;
placing a second substrate against a top surface of the device structure opposite the first substrate and facing the first separation marks;
applying second separation marks on the first substrate on a side of the substrate facing away from the first separation marks, the second separation marks being aligned with the first separation marks; and
applying cuts extending through the first substrate and the second substrate to produce the device die.

2. The method of claim 1, wherein the first substrate is transparent.

3. The method of claim 2, wherein the first substrate is sapphire.

4. The method of claim 1, wherein the device structure is a semiconductor device structure .

5. The method of claim 4, wherein the device structure is an LED device structure.

6. The method of claim 4, wherein the device structure is a detector device structure.

7. The method of claim 4, wherein the device structure is formed so as to have at least two contacts arranged on the top surface.

8. The method of claim 1, further including bonding the first substrate and second substrate.

9. The method of claim 8, wherein the second substrate has contact pads associated with the at least two contacts.

10. The method of claim 1, wherein the second substrate is made of a metal, a semiconductor or a polymer.

11. The method of claim 1, wherein at least one of the first and second substrate is thinned.

12. The method of claim 1, wherein the second substrate includes a reflective layer.

13. The method of claim 12, wherein the reflective layer is dielectric stack.

14. The method of claim 12, wherein the reflective layer is a metal.

15. The method of claim 14, wherein the metal reflective layer is bounded by at least one insulating layer.

16. The method of claim 4, wherein the LED device structure comprises a material selected from the group consisting of Si, (AlGaIn)As, (AlGaIn)P and (AlGaln)N.

17. The method of claim 1, wherein the second substrate is a material selected from the group consisting of Si, GaAs and SiC.

18. The method of claim 7, wherein the at least two contacts are arranged at a different height.

19. The method of claim 8, wherein bonding the wafer includes interposing a metal or a metal compound between the first and the second substrate.

20. The method of claim 1, wherein the cuts through the first and the second substrate are applied at a location that is offset from the first and second separation marks.

21. The method of claim 9, wherein the cuts expose at least one of the contact pads on the second substrate.

22. A method of producing LEDs devices from a substrate wafer having an LED device structure disposed thereon, comprising:
defining LED dies on the LED device structure,
applying contacts to the LED devices that face away from the substrate wafer for supplying an electric voltage to an LED die,
placing a first separation mark between the LED dies on a side of the substrate wafer having the LED device structure,
providing a handling wafer having electrodes disposed thereon, with the electrodes adapted to mate with respective ones of the contacts of the LED structure,
bonding the substrate wafer with the handling wafer so that the electrodes mate with ones respective contacts of the LED structure,
placing a second separation mark substantially aligned with the first separation mark on a side of the substrate wafer facing away from the LED device structure, and
placing a separation cut extending through the substrate wafer and the handling wafer and laterally offset from the first and second separation mark for separating the LED dies to form the LED devices.

23. The method of claim 22, wherein the handling wafer is electrically conducting.

24. The method of claim 22, wherein the substrate wafer is optically transparent.

25. The method of claim 23, wherein electric power is supplied to the LED device through the electrically conducting handling wafer.

26. The method of claim 22, wherein the laterally offset separation cut exposes at least one of the contacts of the handling wafer for supplying electric power to the LED device.

27. The method of claim 24, wherein the substrate wafer is sapphire.

28. The method of claim 24, wherein the handling wafer is made of a metal, a semiconductor or a polymer.

29. The method of claim 1, wherein at least one of the substrate wafer and the handling wafer is thinned.

30. The method of claim 22, wherein the handling wafer includes a reflective layer.

31. The method of claim 30, wherein the reflective layer is dielectric stack.

32. The method of claim 30, wherein the reflective layer is a metal.

33. The method of claim 32, wherein the metal reflective layer is bounded by at least one insulating layer.

34. The method of claim 22, wherein the LED device structure comprises a material selected from the group consisting of (AlGaIn)As, (AlGaln)P and (AlGaIn)N.

35. The method of claim 22, wherein the handling is a material selected from the group consisting of Si, GaAs and SiC.

36. The method of claim 22, wherein the contacts to the LED devices are arranged at a different height.
